(19) United States
(12) Patent Application Publication
(10) Pub. No.: US 2013/0241567 A1
(43) Pub. Date: Sep. 19, 2013

(54) Method for Determining the Life Expectancy of at least One Battery Cell, Battery comprising a Plurality of Battery Cells, and Motor Vehicle

(71) Applicants: Andre Boehm, Kornwestheim (DE); Ralf Piscol, Herrenberg (DE); Joachim Rischen, Lake Orion, MI (US)

(72) Inventors: Andre Boehm, Kornwestheim (DE); Ralf Piscol, Herrenberg (DE); Joachim Rischen, Lake Orion, MI (US)

(73) Assignee: Robert Bosch GmbH, Stuttgart (DE)

(21) Appl. No.: 13/809,890

(22) PCT Filed: May 17, 2011
(86) PCT No.: PCT/EP2011/057917

§ 371 Date: May 24, 2013

(30) Foreign Application Priority Data
Jul. 14, 2010 (DE) 10 2010 031 337.8

(51) Int. Cl. G01R 31/36

(52) U.S. Cl. CPC G01R 31/3606
USPC 324/434

(57) ABSTRACT

A method for determining the life expectancy of at least one battery cell, according to which a value of at least one physical variable acting on the battery cell and/or a number of executions of at least one process taking place in the battery cell is determined, and the value of the physical variable and/or the number of executions of processes is used as a basis for determining the life expectancy. The physical variable and/or the number of executions of processes taking place in the battery cell is determined for a plurality of operating cycles, and the frequency of the occurrence of defined values of the physical variable and/or the frequency of the number of executions of at least one defined process is stored.

The present invention relates to a method for determining the life expectancy of at least one battery cell, in which a value of at least one physical variable which acts on the battery cell and/or the number of times that at least one process which takes place in the battery cell is carried out are/is determined and the value of the physical variable and/or the number of times that processes are carried out are/is used as the basis for determining the life expectancy.

Furthermore, the present invention relates to a battery, in particular to a lithium-ion battery or a nickel-metal hydride battery, which has a plurality of battery cells and at least one battery management system, wherein the battery management system is designed to carry out the method according to the invention for determining the life expectancy of the battery cell.

Furthermore, the present invention relates to a motor vehicle having a battery according to the invention.

### PRIOR ART

A battery which comprises one or more galvanic battery cells serves as an electrochemical energy store and energy converter. When the battery or the respective battery cell is discharged, chemical energy stored in the battery is converted into electrical energy by intercalation.

This electrical energy can therefore be requested by a user depending on demand.

In particular, in hybrid vehicles and electric vehicles, lithium-ion batteries or nickel-metal hydride batteries which are composed of a large number of electrochemical cells connected in series are used in what are referred to as battery packs. Usually, a battery management system, including a battery state detection means, serves to monitor the safety and to ensure the longest possible service life.

Different approaches are known for monitoring the functional reliability and detecting the state of health of battery cells, in particular of cells of lithium-ion batteries. The voltage and current strength made available by battery cells or an entire battery is usually recorded, if appropriate using further factors as power parameters. This means that physical parameters of the battery cells are measured, calculated or estimated and conclusions about the state of health, and accordingly about the functional reliability, are drawn therefrom. In this context, the values which can be determined per operating cycle are generally used.

DE 103 28 721 A1 discloses a method for predicting a residual service life of an electric energy store such as, for example a battery or battery cell.

In this context, physical variables generated by the respective battery or battery cell are determined as a function of further external influences such as, for example, the temperature. The determination is carried out here by means of calculation. However, the number of certain processes which have taken place and/or certain values of some physical variables are not included in the calculation.

### DISCLOSURE OF THE INVENTION

According to the invention, a method is made available for determining the life expectancy of at least one battery cell, in which a value of at least one physical variable which acts on the battery cell and/or the number of times that at least one process which takes place in the battery cell is carried out are/is determined and the value of the physical variable and/or the number of times that processes are carried out are/is used as the basis for determining the life expectancy, wherein the physical variable and/or the number of times that processes which take place in the battery cell are carried out are/is determined for a plurality of operating cycles, and the frequency of occurrence of certain values of the physical variable and/or the frequency of the number of times that at least one specific process is carried out are/is stored.

The battery cells which are subjected to the method according to the invention are preferably a component of a plurality of battery cells such as are arranged, for example, in a single battery.

In one particular refinement, just one battery cell is present per battery, with the result that the method according to the invention can also be used for determining the life expectancy of the entire battery.

In addition, the method can also be carried out in such a way that a value of at least one physical variable which acts on the entire battery and/or the number of times that at least one process which takes place in the entire battery is carried out is determined and the frequency of occurrence of certain values of the physical variable and/or the frequency of the number of times that at least one certain process is carried out are/is stored, specifically even in the case when the battery has a plurality of battery cells.

However, the method according to the invention is explained below on the basis of its application for a single battery cell.

By determining the life expectancy of the individual battery cells it is possible to draw conclusions about the service life of the entire battery. The method according to the invention can also serve to determine the state of health. The physical variable is preferably measured and the determination of the number of times that at least one process which takes place in the battery cell is carried out preferably takes place by means of counting. The start of the operating cycle is defined by the start of the activation of the battery cell and the ending of the operating cycle is defined by the ending of the activation of the battery cell.

The activation phase can comprise merely one driving cycle here, or a driving cycle with subsequent charging process. Alternatively, the activation phase can also comprise a charging process independently of a driving cycle.

Furthermore, the activation phase can also comprise controlled discharging of the cell, subsequent to the driving cycle, in order to implement the equalization of the states of charge of a plurality of cells, referred to as cell balancing, subsequent to the driving cycle or even during the driving cycle.

The start of the operating cycle can therefore be, for example, the starting of a motor vehicle which is driven with the battery cells. The ending of the operating cycle can correspond to the switching off of this motor vehicle. If a charging process of the battery cell is directly connected chronologically to the operation of the motor vehicle, the operating cycle also comprises the time of charging. It is therefore possible, for example, for the ending of the operating cycle in the case of a charging process subsequent to the travel of the motor vehicle to take place only after the ending of the charging process.

### ADVANTAGES OF THE INVENTION

The method according to the invention determines values or states of the battery cell over a plurality of operating cycles. As a result, cell defects can be detected early and therefore prevented. Furthermore, precise findings with respect to the life expectancy or the state of health of the battery cell are possible, from which suitable modes of operation for the battery cell or for an entire battery can be derived. In the case of what are referred to as field returns, that is to say batteries which are subjected to an examination after a theoretical service life of, for example, a kilometerage of over 100,000 km in a motor vehicle, it is possible to analyze how the cells have been loaded over the sum of their operating times, and as a result their properties have changed. Valuable findings for further optimization of the cells and/or of the battery management system can be acquired therefrom. The method according to the invention can be applied to lithium-ion batteries as well as to nickel-metal hydride batteries. The method is preferably used in a plurality of cells, and in particular in all the cells, of one or more batteries which are operated substantially at the same time.

The physical variable whose values are determined according to the invention in terms of their frequency may be, for example, the temperature, the state of charge, the current which is output by the battery cell or the voltage which is present in the battery cell. The difference between a minimum and a maximum state of charge and/or the relative cell power, specifically the power which is currently retrieved as a ratio to the currently maximum available power, can also be determined, derived from the state of charge.

The process which is determined in terms of its frequency and which takes place in the battery cell may be a charging pulse, a discharging pulse or controlled discharging of the cell for implementing the equalization of the states of charge of a plurality of cells.

The controlled discharging of the cell for implementing the equalization of the states of charge of a plurality of cells, also referred to as cell balancing, can preferably be implemented for lithium-ion battery cells. This cell balancing serves to avoid serious differences in terms of the states of charge of individual cells. It has become apparent that in order to achieve a long service life it is more advantageous to keep the difference between the states of charge of individual cells of a battery small than to maintain relatively high states of charge in some cells compared to relatively low states of charge in other cells. For this purpose, the cells are discharged in a controlled fashion up to the state of charge which corresponds to the state of charge of the cell which is charged the least. The frequency of the controlled discharging of a cell is therefore a criterion for its state of health. Those cells which are subjected to the controlled discharging process the least are therefore those which have the lowest states of charge compared to other battery cells. In order to increase the power and service life of the entire battery, such cells therefore have to be replaced first.

The value of the physical variable and/or the number of times that the processes are carried out per operating cycle are/is advantageously stored in at least one nonvolatile memory, and the frequency of occurrence of certain values of the physical variable and/or the frequency with which a certain number of processes are carried out are/is read of the memory. Such a nonvolatile memory is, for example, what is referred to as an EEPROM (an electrically erasable programmable read-only memory). The advantage of this configuration of the method is the simple storage over a plurality of operating cycles and the possibility of evaluating the stored values in terms of their frequency.

The number of times that at least one certain value of a physical variable occurs and/or the number of times that processes are carried out are/is determined over a plurality of operating cycles.

The number of values or times a process is carried out which is determined for each operating cycle is added to the previously determined numbers and stored.

That is to say with each operating cycle the corresponding number is determined and is added to the numbers determined for the previous operating cycles, and the result is stored.

It is therefore possible to evaluate how often over the operating cycles, for example, a certain charge was present and/or a certain temperature was present and/or a discharging pulse took place and/or controlled discharging of the cells took place.

In order to evaluate the method results, the frequency of occurrence of certain values of the physical variable and/or the frequency with which a certain number of processes is carried out are/is represented in a visually perceptible fashion in at least one diagram. In such a diagram, values of the physical variable or the number of processes are to be plotted on the abscissa, and the frequency of occurrence of the respective value of the physical variable or the frequency with which the number of processes is carried out are to be plotted on the ordinate. A person can read off from the diagram what value of a physical variable or what number of processes particularly frequently occurred, from which conclusions can be drawn about the state of health of the battery cell and/or about the mode of operation to be aimed at.

The method is advantageously configured in such a way that the value of a first physical variable or the number of times that a first process which takes place in the battery cell is carried out are/is stored as a function of the value of a second physical variable or of a number of times that a second process takes place in the battery cell. There is also provision here that the physical variable and/or the number of processes per operating cycle are stored as a function of one another in at least one nonvolatile memory, and the frequency of occurrence of certain values of the physical variable and/or the frequency of times a certain number of processes is carried out, which number has been determined by addition over a plurality of operating cycles, are/is read out of the memory. The advantage of this configuration of the method is the sensing of the variables as a function of one another, with the result that a relatively small memory requirement is necessary and accordingly the use of the nonvolatile memories can be implemented more easily.

In the last-mentioned configuration of the method it is advantageous if the frequency of occurrence of certain values of the physical variables is represented as a function of one another and/or the frequency with which a certain number of processes are carried out is represented as a function of one another, in a visually perceptible fashion in at least one three-dimensional histogram. In such a three-dimensional histogram, the values of the first physical variable or the number of first processes can be plotted on the first abscissa, and the values of the second physical variable or the number of second processes can be plotted on the second abscissa. The frequency of occurrence of the respective value of the physical variable or the number of times that the processes are carried out as a function of one another can be plotted on the ordinate. The invention is not restricted here to sensing two physical variables as a function of one another or two different processes as a function of one another but instead it is also possible to evaluate a physical variable and a process as a function of one another in terms of their frequency. Such histograms are stored and read out again after a reset of the battery management system and used for further calculation, also for further addition of further frequencies of occurrence of certain values of the physical variable and/or frequencies of the time that a certain number of processes are carried out. The state of health and the service life can be calculated from the histogram by means of suitable algorithms. A decisive value for the calculation can be the frequency of occurrence of a certain physical variable or of a certain number of processes.

A person can detect from the histogram which physical parameters and/or which processes have most influence on the service life of the battery cell and/or which devices of the battery management system must, under certain circumstances, be adjusted in order, for example, to vary the temperature of a number of cells. However, the values which can be derived from the histogram can also be used immediately in the battery management system as open-loop and/or closed-loop control signals for the operation of the battery cell or of an entire battery, in order to prevent premature ageing phenomena or wear phenomena.

In one preferred refinement of the method according to the invention, in a certain value range in which it has been empirically found that the values of the physical variable, determined over a plurality of operating cycles and/or of the number of processes which take place in the battery cell are located, reference points are defined which each represent the limits of ranges whose frequency of occurrence is determined. It is therefore possible, for example, to define a temperature value range between −40° C. and 80° C.

The reference points are preferably parameterizable, that is to say they are defined in such a way that suitable ranges are formed with respect to the information relating to certain physical variables or certain numbers of processes. It is possible, for example in the ranges in which generally a relatively high frequency is found to occur, to make the ranges shorter in order thereby to permit more differentiated information relating to the service life during the operation of the battery cell with the values of the physical variable in this range or the values of the number of processes in this range. That is to say the distances between adjacent reference points may differ from one another in size.

Alternatively, the reference points can also be defined at regular ranges, such as, for example at distances of 20° C.

The range at which a certain physical variable or the number of processes occurs is preferably determined at regular time intervals. For this range, the frequency is determined over a plurality of operating cycles. Suitable time intervals are here, for example, between 0.5 and 2 seconds. The range at which the value of a certain physical variable or the number of certain processes is located is preferably determined every second.

When the method according to the invention for implementing the specified diagrams is configured it is possible, for example, to represent in a visually perceptible fashion the frequency with which the battery cell has a charging power of 50 to 60% of the maximum charging power. In this case, reference points are provided at 50 and 60 percent.

When the method for obtaining histograms is carried out it is possible, for example, to detect the frequency of current strengths in a certain current strength range as a function of temperatures in a certain temperature range of the battery cell. It is therefore possible to determine, for example, the frequency with which a current of, for example, 75 to 85% of the maximum current which can be generated has been generated if the battery cell was operated within a temperature range of 40 to 50° C.

By evaluating the frequencies it is possible to draw conclusions about the state of health of the battery cell, for example if at relatively low temperatures it is only rarely able to generate a certain percentage of a theoretically achievable maximum current strength. Furthermore, the evaluation of the frequency makes it possible to determine how frequently certain external parameters act on the battery cell, with the result that the battery management system can be correspondingly adapted. This relates, for example, to adaptation measures relating to the battery cell temperature and number of charging pulses and discharging pulses.

According to the invention, a battery, in particular a lithium-ion battery or a nickel-metal hydride battery, is also made available which comprises a plurality of battery cells and at least one battery management system and can be connected to a drive system of a motor vehicle, wherein the battery management system is designed to implement the method according to the invention. The battery cells are preferably combined spatially here and connected to one another by circuitry.

The invention is supplemented by a motor vehicle, in particular a motor vehicle which can be driven by an electric motor and which comprises at least one battery according to the invention, wherein the battery is connected to a drive system of the motor vehicle.

The determination of the life expectancy of at least one battery cell can take place in a computer-assisted fashion, with the aid of a computer program which, after it has been loaded in the storage means of a data processing device, permits said data processing device to carry out the method according to the invention for determining the life expectancy of at least one battery cell. In addition, for this purpose a computer-readable storage medium is made available on which a program is stored which, after it has been loaded in the storage means of a data processing device, permits said data processing device to carry out the method according to the invention. A further addition is a method in which the computer program for carrying out the method according to the invention is downloaded from an electronic data network, such as for example from the Internet, onto a data processing device which is connected to the data network.

### DRAWINGS

Exemplary embodiments of the invention are explained in more detail with reference to the drawings and the following description. In the drawings:

FIG. 1 shows a diagram produced by means of the method according to the invention, and

FIG. 2 shows a three-dimensional histogram produced by means of the method according to the invention.

### EMBODIMENTS OF THE INVENTION

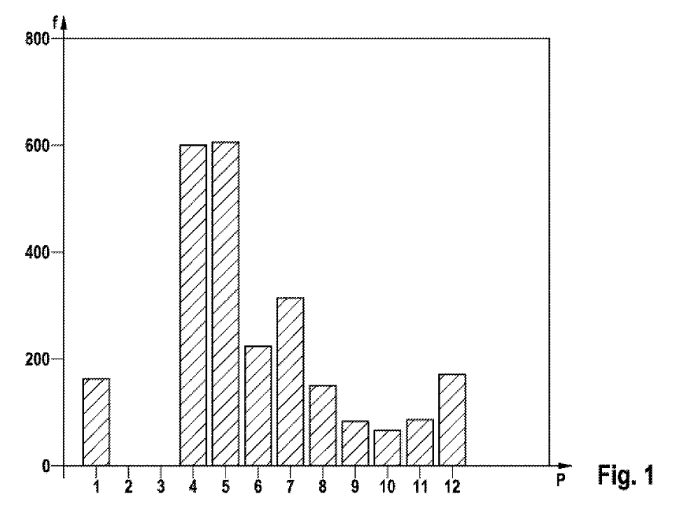

FIG. 1 illustrates as a result of an alternative of the method according to the invention a diagram which represents by way of example the frequency f of occurrence of a current charging power P. The current charging power P is plotted on the abscissa, and the frequency f on the ordinate. It is apparent that the value range of the current charging power P has been divided into ranges which are numbered from 1 to 12. Each of these ranges 1 to 12 is assigned a value range of the current charging power P. The size of the value ranges can vary here. From FIG. 1 it is apparent that, for example, the current charging power P of the range 5 occurred most frequently. It is therefore possible to convey visually to a person that over a plurality of operating cycles the respective battery cell had most frequently a charging power P which is defined by the range 5. That is to say charging powers P according to the range 5 occurred substantially more frequently than a maximum charging power P according to the range 12. A conclusion from this realization could be that the charging power P is often below the maximum possible charging power, with the result that maintenance measures should be carried out or, if appropriate, the battery cell or battery replaced, in order to ensure the functional reliability of an electro-motive drive of a motor vehicle.

The same process can also be carried out at a battery having one or more battery cells, wherein the charging power of the entire battery is evaluated.

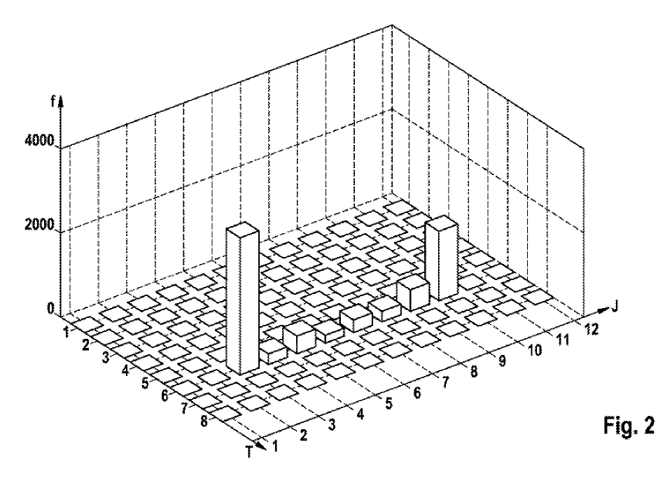

The three-dimensional histogram which is illustrated in FIG. 2 and which can be generated according to the invention in accordance with a further method alternative shows the frequency f of occurrence of current strengths l in a certain range as a function of temperatures T in a certain temperature range of the respective battery cell. The current strength l is plotted on the first abscissa in the ranges 1 to 12. The temperature T is plotted in the ranges 1 to 8 on the second abscissa. The frequency f is plotted on the ordinate. From the three-dimensional histogram it is apparent that current strengths l according to the current strength range 3 have been generated with by far the greatest frequency at temperatures which correspond to the temperature range 6. Current strengths which are in the current strength range 10, specifically also in the temperature range 6, were generated with the second largest frequency. Important information from this three-dimensional histogram is also that all the current strengths l were generated merely in the temperature range 6. Insofar as it is possible to determine that the respective battery cell was also operated in temperature ranges which differ from the temperature range 6, it is possible to draw the conclusion that in these differing temperature ranges no current was generated by means of the battery cells. This is also information which can be used to calculate and/or estimate the state of health or the service life of the respective battery cell. Furthermore, the realization that the battery cell should preferably be operated merely in the temperature range 6 arises from this.

The invention is not restricted to a situation in which only physical variables such as, for example, the current strength l and the temperature T are represented as a function of one another in the three-dimensional histogram but, in contrast to this, the method according to the invention can also be carried out in such a way that the histogram represents the number of times that processes are carried out as a function of one another or said histogram represents a physical variable as a function of the number of times that processes are carried out, or vice versa.

It is possible, for example, to combine the physical variable and temperature, the state of the battery, characterized by its charge as a percentage, the difference between the minimum and maximum cell battery state, the relative battery power which corresponds to the power currently retrieved in comparison with the currently available maximum power, and the number of times that charging pulses and discharging pulses are carried out with one another in the three-dimensional histogram. Advantageous combinations of the physical variables on the two abscissae of the three-dimensional histogram are the minimum cell voltage and the temperature, the maximum cell voltage and the temperature, the current strength and the temperature as well as the currently retrieved power and the temperature.

1. A method for determining the life expectancy of at least one battery cell, comprising:
determining (i) a value of at least one physical variable which acts on the battery cell and/or (ii) the number of times that at least one process which takes place in the battery cell is carried out;
using the value of the physical variable and/or the number of times that processes are carried out as the basis for determining the life expectancy;
determining the physical variable and/or the number of times that processes which take place in the battery cell are carried out for a plurality of operating cycles; and
storing (i) the frequency of occurrence of certain values of the physical variable and/or (ii) the frequency of the number of times that at least one specific process is carried out.

2. The method for determining the life expectancy of at least one battery cell as claimed in claim 1, wherein the physical variable is the temperature, the state of charge, the current which is output by the battery cell, or the voltage which is present in the battery cell.

3. The method for determining the life expectancy of at least one battery cell as claimed in claim 1, wherein the process which takes place in the battery cell is a charging pulse, a discharging pulse, or controlled discharging of the cell for implementing the equalization of the states of charge of a plurality of cells.

4. The method for determining the life expectancy of at least one battery cell as claimed in claim 1, wherein:
the value of the physical variable and/or the number of times that the processes are carried out per operating cycle are/is stored in at least one nonvolatile memory, and
the frequency of occurrence of certain values of the physical variable and/or the frequency of the number of times that a certain process is carried out are/is read of the memory.

5. The method for determining the life expectancy of at least one battery cell as claimed in claim 4, wherein the frequency of occurrence of certain values of the physical variable and/or the frequency of the number of times that a certain process is carried out are/is represented in a visually perceptible fashion in at least one diagram.

6. The method for determining the life expectancy of at least one battery cell as claimed in claim 4, wherein the value of a first physical variable or the number of times that a first process which takes place in the battery cell is carried out are/is stored as a function of the value of a second physical variable or of a number of times that a second process is carried out in the battery cell.

7. The method for determining the life expectancy of at least one battery cell as claimed in claim 6, wherein:
the frequency of occurrence of certain values of the physical variable is represented as a function of one another, and/or
the frequency of the number of times that a certain process is carried out is represented as a function of one another in a visually perceptible fashion in at least one three-dimensional histogram.

8. The method for determining the life expectancy of at least one battery cell as claimed in claim 1, wherein in the value range of the physical variable, determined over a plurality of operating cycles, and/or of the number of times that processes which take place in the battery cell are carried out, reference points are defined which each represent the limits of ranges whose frequency of occurrence is determined.

9. A battery, comprising:
a plurality of battery cells; and
at least one battery management system configured to be connected to a drive system of a motor vehicle,
wherein the at least one battery management system is configured to implement a method for determining the life expectancy of at least one battery cell,
wherein the method includes
(i) determining a value of at least one physical variable which acts on the battery cell and/or the number of times that at least one process which takes place in the battery cell is carried out,
(ii) using the value of the physical variable and/or the number of times that processes are carried out as the basis for determining the life expectancy,
(iii) determining the physical variable and/or the number of times that processes which take place in the battery cell are carried out for a plurality of operating cycles, and
(iv) storing the frequency of occurrence of certain values of the physical variable and/or the frequency of the number of times that at least one specific process is carried out.

10. A motor vehicle, comprising:
at least one battery including (i) a plurality of battery cells, and (ii) at least one battery management system configured to be connected to a drive system of the motor vehicle,
wherein the at least one battery management system is configured to implement a method for determining the life expectancy of at least one battery cell,
wherein the method includes
(i) determining a value of at least one physical variable which acts on the battery cell and/or the number of times that at least one process which takes place in the battery cell is carried out,
(ii) using the value of the physical variable and/or the number of times that processes are carried out as the basis for determining the life expectancy,
(iii) determining the physical variable and/or the number of times that processes which take place in the battery cell are carried out for a plurality of operating cycles, and
(iv) storing the frequency of occurrence of certain values of the physical variable and/or the frequency of the number of times that at least one specific process is carried out.
